(19) United States
(12) Patent Application Publication
(10) Pub. No.: US 2010/0330711 A1
(43) Pub. Date: Dec. 30, 2010

(54) METHOD AND APPARATUS FOR INSPECTING SCRIBES IN SOLAR MODULES

(75) Inventor: Asaf Schlezinger, Sunnyvale, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/492,989

(22) Filed: Jun. 26, 2009

(51) Int. Cl. H01L 21/66; G01N 21/88

(52) U.S. Cl. 438/7; 356/237.2; 257/E21.53

(57) ABSTRACT

Embodiments of the present invention generally relate to a method and apparatus for inspecting and analyzing the spacing of isolation trenches scribed in a solar module during the fabrication process. In one embodiment, images of the scribed trenches are captured and analyzed at various points in the fabrication process. The results may then be used either manually or in an automated fashion to diagnose, alter, and tune upstream processes for improved scribe spacing on subsequently processed solar modules.

### BACKGROUND OF THE INVENTION

1. Field of the Invention

Embodiments of the present invention generally relate to the fabrication of photovoltaic modules. In particular, embodiments of the present invention relate to apparatus and methods for inspecting scribes in solar modules during the fabrication process.

2. Description of the Related Art

Photovoltaic (PV) cells or solar cells are devices that convert sunlight into direct current (DC) electrical power. Typical thin film solar cells have a PV layer comprising one or more p-i-n junctions. Each p-i-n junction comprises a p-type layer, an intrinsic type layer, and an n-type layer. When the p-i-n junction of the solar cell is exposed to sunlight (consisting of energy from photons), the sunlight is converted to electricity through the PV effect.

Thin film solar cells are typically formed in series on a large area substrate to form a solar module. The solar modules are formed by scribing trenches in the various thin film layers deposited on the large area substrate during the fabrication process to both isolate and electrically connect the solar cells in series. In order to maximize the efficiency of the solar module, the spacing of the various scribed trenches should be minimized. However, certain scribing issues, such as waviness, non-linearism, or non-parallelism of the scribed trenches, are experienced during the solar module fabrication process. Such issues lead to non-functioning or “dead” cells resulting in significant losses in the efficiency of the solar module. Moreover, these “dead” cells are typically not discovered until final testing of the completed solar module using prior are process sequences and fabrication techniques.

Therefore, there is a need for a method and apparatus for inspecting scribes during the fabrication of a solar module. Additionally, there is a need for a process and system for fabricating solar modules incorporating scribe inspection and using the results of the inspection to diagnose and alter upstream processes to improve the various scribing processes and reduce or prevent the occurrence of “dead” solar cells in solar modules.

### SUMMARY OF THE INVENTION

In one embodiment of the present invention, an apparatus for inspecting scribed trenches in a partially formed solar module comprises a first illumination source positioned to illuminate a back surface of the partially formed solar module, an inspection device positioned to capture an image from the back surface of the partially formed solar module, and a system controller in communication with the first illumination source and the inspection module, wherein the system controller is configured to receive and analyze the image received from the inspection device.

In another embodiment, a method of inspecting scribed trenches in a partially formed solar module comprising receiving the partially formed solar module having at least a front contact layer disposed thereon with one or more first trenches scribed in the front contact layer and a photovoltaic layer disposed over the front contact layer having one or more second trenches scribed in the photovoltaic layer, illuminating a back surface of the partially formed solar module, and optically inspecting a region of the partially formed solar module having at least a portion of the one or more first trenches and at least a portion of the one or more second trenches disposed therein while illuminating the back surface of the partially formed solar module. In one embodiment, optically inspecting comprises capturing an image of the region and analyzing a position or orientation of the portion of the one or more first trenches relative to the portion of the one or more second trenches.

In another embodiment, a system for fabricating solar modules comprises a first scribing module configured to scribe one or more first trenches in a front contact layer of a solar cell substrate, one or more cluster tools having at least one chamber configured to deposit at least one photovoltaic layer over the front contact layer, a second scribing module configured to scribe one or more second trenches in the at least one photovoltaic layer, a first optical inspection module having a first illumination source and an inspection device configured to capture an image of the first and second trenches, and a system controller in communication with at least the first scribing module, the second scribing module, and the optical inspection module. In one embodiment, the system controller is configured to receive and analyze the image of the portion of the first and second trenches. In one embodiment, the system controller is further configured to alter parameters of at least one of the first and second scribing modules in response to the analyzed image.

In yet another embodiment, a process for fabricating solar modules comprises receiving a solar cell substrate having at least a front contact layer disposed thereon, scribing one or more first trenches in the front contact layer via a first scribing module, depositing a photovoltaic layer over the front contact layer, scribing one or more second trenches in the photovoltaic layer via a second scribing module, capturing an image of at least a portion of the first and second trenches while illuminating a back surface of the solar cell substrate, analyzing the captured image of the at least a portion of the first and second trenches by analyzing a position or orientation of at least a portion of the one or more first trenches with respect to at least a portion of the one or more second trenches, and altering one or more parameters of at least one of the first and second scribing modules based on the analyzed image of the at least a portion of the first and second trenches.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a simplified, schematic flow chart illustrating one embodiment of a process sequence for forming a solar module.

FIG. 2 is a simplified, schematic plan view of one embodiment of a solar module production line.

FIG. 3 is a schematic plan view of a solar module comprising a plurality of solar cells formed on a substrate.

FIG. 4 is a schematic cross-sectional view of a portion of the solar module along section line 4-4 shown in FIG. 3.

FIGS. 5A-5E represent enlarged views of a region of the solar module depicted in FIG. 3 illustrating possible orientations of scribed trenches.

FIG. 6 is a schematic isometric view of a laser scribe module that may be used for laser scribing a series of trenches in one or more material layers deposited on a solar cell substrate.

FIG. 7A is a schematic, cross-sectional view of an inspection module according to one embodiment of the present invention.

FIG. 7B is a schematic, cross-sectional view of an inspection module according to another embodiment of the present invention.

### DETAILED DESCRIPTION

Embodiments of the present invention generally relate to a method and apparatus for inspecting and analyzing the spacing of isolation trenches scribed in a solar module during the fabrication process. In one embodiment, images of the scribed trenches are captured and analyzed at various points in the fabrication process. The results may then be used either manually or in an automated fashion to diagnose, alter, and tune upstream processes for improved scribe spacing on subsequently processed solar modules.

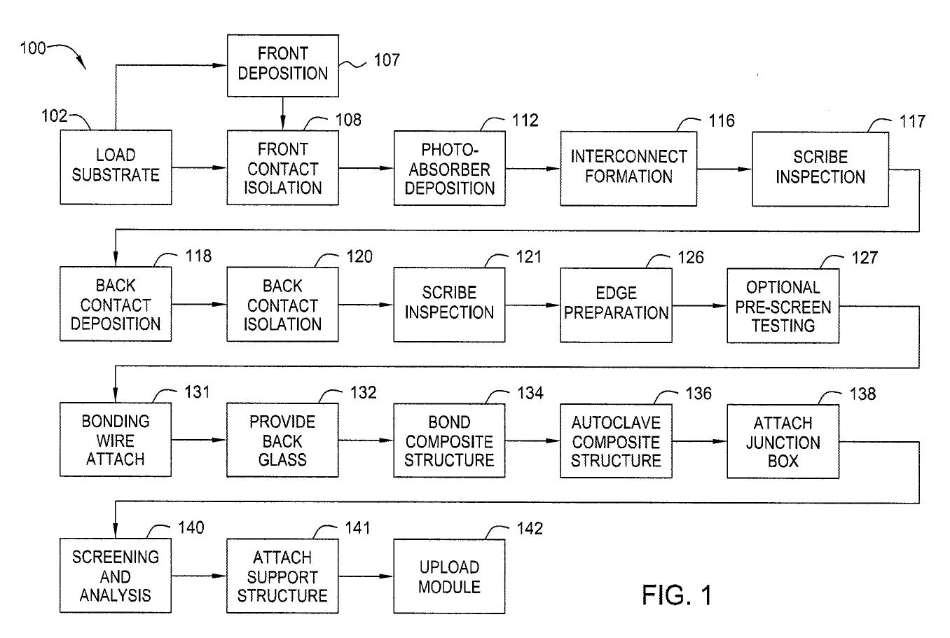

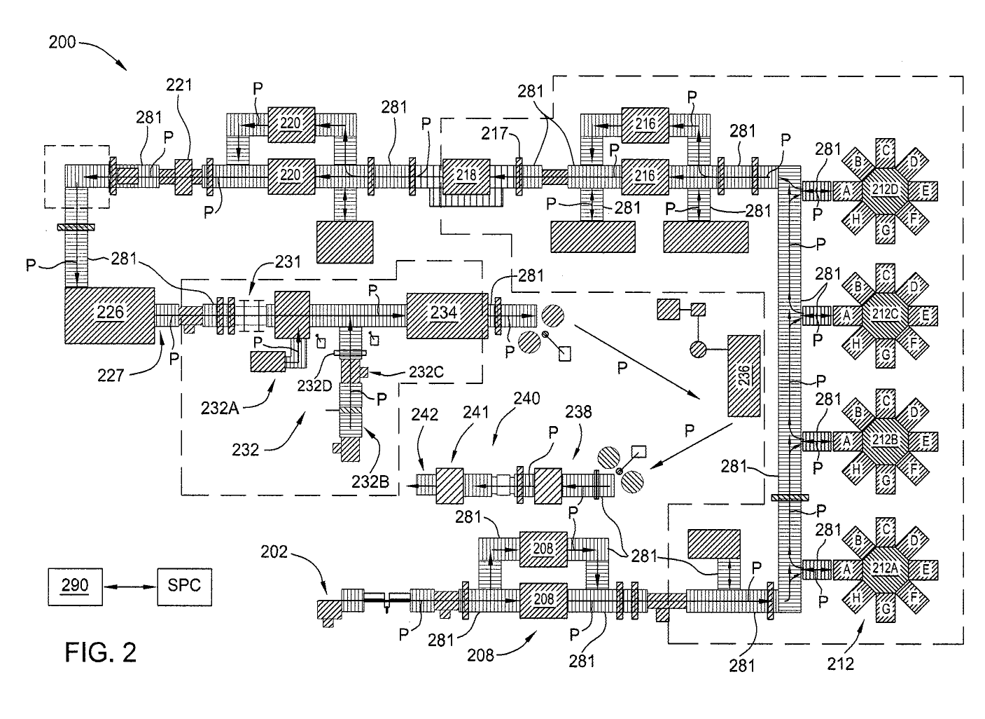

FIG. 1 is a simplified, schematic flow chart illustrating one embodiment of a process sequence 100 including a plurality of processes used to form a solar module 300 using a solar module production line 200. FIG. 2 is a simplified, schematic plan view of one embodiment of the production line 200 illustrating process modules and other aspects of the system design.

In general, a system controller 290 may be used to control one or more components found in the production line 200. The system controller 290 generally facilitates the control and automation of the overall production line 200 and typically includes a central processing unit (CPU) (not shown), memory (not shown), and support circuits (or I/O) (not shown). The CPU may be one of any form of computer processors that are used in industrial settings for controlling various system functions, substrate movement, chamber processes, and support hardware (e.g., sensors, robots, motors, lamps, etc.), and monitor the processes (e.g., substrate support temperature, power supply variables, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 290 determines which tasks are performable on a substrate. Preferably, the program is software readable by the system controller 290 that includes code to perform tasks relating to monitoring, execution and control of the movement, support, and/or positioning of a substrate along with the various process recipe tasks and various chamber process recipe steps being performed in the production line 200. In one embodiment, the system controller 290 also contains a plurality of programmable logic controllers (PLC's) that are used to locally control one or more modules in the solar cell production, and a material handling system controller (e.g., PLC or standard computer) that deals with the higher level strategic movement, scheduling and running of the complete production line 200.

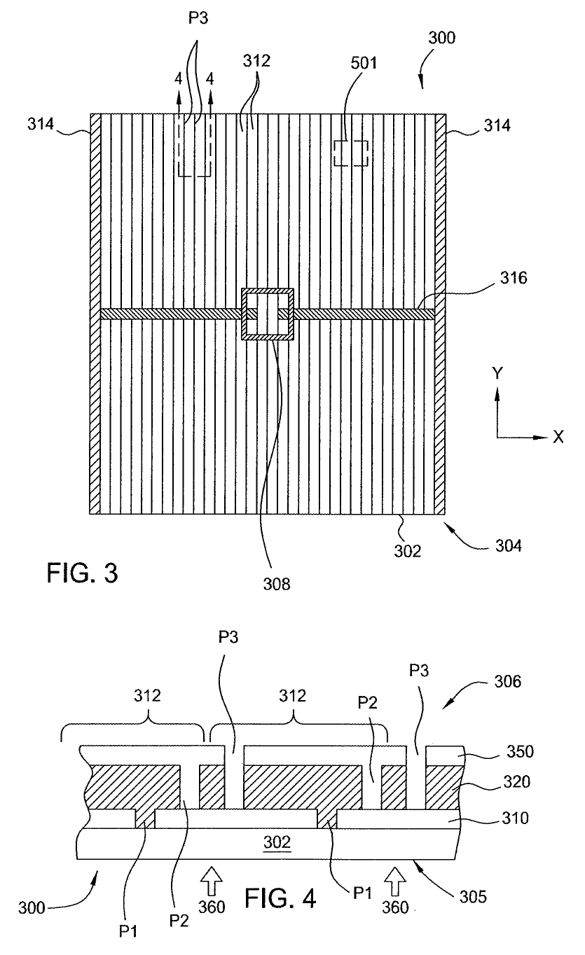

FIG. 3 is a schematic plan view of a solar module 300 having a plurality of solar cells 312 formed on a substrate 302. The plurality of solar cells 312 are electrically connected in series and are electrically connected to side busses 314 located at opposing ends of the solar module 300. A cross-buss 316 is electrically connected to each of the side busses 314 to collect the current and voltage generated by the solar cells 312. A junction box 308 acts as an interface between leads (not shown) from the cross-busses 316 and external electrical components that will connect to the solar module 300, such as other solar modules or a power grid.

In order to form a desired number and pattern of solar cells 312 on the substrate 302, a plurality of scribing processes may be performed on material layers formed on the substrate 302 to achieve cell-to-cell and cell-to edge isolation. FIG. 4 is a schematic cross-sectional view of a portion of the solar module 300 along section line 4-4 shown in FIG. 3. As shown, the solar module 300 includes the substrate 302, such as a glass substrate, polymer substrate, metal substrate, or other suitable substrate, having a front surface 305 with thin films formed over the substrate 302 on a back surface 306 opposite the front surface 305 of the substrate 302. In one embodiment, the substrate 302 is a glass substrate that is about 2200 mm×2600 mm×3 mm in size. The solar module 300 further includes a front contact layer 310 formed over back surface 306 of the substrate 302. The front contact layer 310 may be any optically transparent and electrically conductive film, such as a transparent conducting oxide (TCO), formed to serve as a front contact electrode for the solar cells 312. Examples of TCO include zinc oxide (ZnO) and tin oxide (SnO). The solar module 300 further includes a photovoltaic (PV) layer 320 formed over the front contact layer 310 and a back contact layer 350 formed over the PV layer 320.

The PV layer 320 may include a plurality of silicon film layers that includes one or more p-i-n junctions for converting energy from incident photons 360 into electricity through the PV effect. In one configuration, the PV layer 320 comprises a first p-i-n junction having a p-type amorphous silicon layer, and intrinsic type amorphous silicon layer formed over the p-type amorphous silicon layer, and an n-type amorphous silicon layer formed over the intrinsic type amorphous silicon layer. In one example, the p-type amorphous silicon layer is formed to a thickness between about 60 Å and about 300 Å, the intrinsic type amorphous silicon layer is formed to a thickness between about 1500 Å and about 3500 Å, and the n-type amorphous semiconductor layer is formed to a thickness between about 100 Å and about 500 Å. In one embodiment, instead of the n-type amorphous silicon layer, an n-type microcrystalline semiconductor layer is formed to a thickness between about 100 Å and about 400 Å.

In another configuration, the PV layer 320 further comprises a second p-i-n junction over the first p-i-n junction. In one example, the second p-i-n junction comprises a p-type microcrystalline silicon layer formed to a thickness from about 100 Å and about 400 Å, an intrinsic type microcrystalline silicon layer formed to a thickness between about 10,000 Å and about 30,000 Å over the p-type microcrystalline silicon layer, and an n-type amorphous silicon layer formed over the intrinsic type microcrystalline silicon layer at a thickness between about 100 Å and about 500 Å.

The back contact layer 350, which is formed over the PV layer 320, may include one or more conductive layers adapted to serve as a back electrode for the solar cells 312. Examples of materials that may comprise the back contact layer 350 include, but are not limited to aluminum (Al), Silver (Ag), titanium (Ti), chromium (Cr), gold (Au), copper (Cu), platinum (Pt), alloys thereof, or combinations thereof.

Three scribing steps may be performed to produce trenches P1, P2, and P3, which are required to form a high efficiency solar cell device, such as the solar module 300. Although formed together on the substrate 302, the individual solar cells 312 are isolated from each other by the insulating trench P3 formed in the back contact layer 350 and the PV layer 320. In addition, the trench P2 is formed in the PV layer 320 so that the back contact layer 350 is in electrical contact with the front contact layer 310. In one embodiment, the insulating trench P1 is formed by laser removal of a portion of the front contact layer 310 prior to the deposition of the PV layer 320 and the back contact layer 350. Similarly, in on embodiment, the trench P2 is formed in the PV layer 320 by the laser scribe removal of a portion of the PV layer 320 prior to the deposition of the back contact layer 350. Finally, in one embodiment, the trench P3 is formed by the laser removal of portions of the back contact layer 350 and the PV layer 320. Although the scribing steps are generally described through this specification with respect to laser scribing, embodiments of the present invention are not intended to be so limited, as they are equally applicable to other forms of scribing trenches in material layers of the solar module 300, such as water jet or diamond scribing, among others.

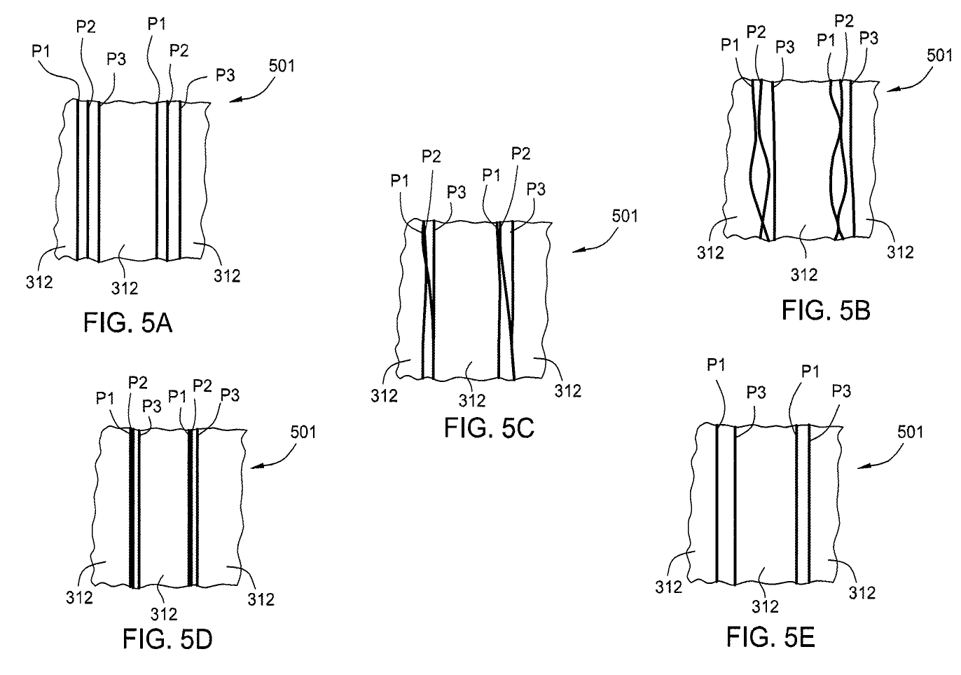

FIGS. 5A-5E represent enlarged views of a region 501 of the solar module 300 depicted in FIG. 3 illustrating possible orientations of the trenches P1, P2, and P3. It should be noted that although FIGS. 5A-5E are depicted displaying all three trenches, this is not representative of an actual visual inspection of the trenches formed in the layers of a solar module 300 using prior art methods because the back contact layer 350 is typically non-translucent. Therefore, such clear visual inspection from either the substrate 302 side or the back contact layer 350 side is not viable using prior art methods.

Referring to FIG. 5A, the trenches P1, P2, and P3 are ideally scribed in lines parallel to one another and tightly spaced (e.g., 240 um) with respect to one another. However, slight variations in the positioning or orientation of the substrate 302 during scribing and/or the laser scribing tool process parameters may lead to discrepancies from the ideal positioning of the scribed trenches, resulting in a fully formed solar module 300 having one or more non-functioning or “dead” solar cells 312. For instance, on a particular substrate 302, one or more of the scribed trenches (P1, P2, or P3) may be wavy resulting in one or more overlapping regions as shown in FIG. 5B. In another example, two or more of the scribed trenches (P1, P2, or P3) may be non-parallel, also resulting in overlapping regions, as shown in FIG. 5C. In another example, one or more of the scribed trenches (P1, P2, or P3) may be mis-spaced or missing, resulting in overlapping or “dead” regions, as shown in FIG. 5D and FIG. 5E, respectively. Thus, it is desirable to inspect and monitor the scribed trenches (P1, P2, and P3) during the solar module formation process in order improve processes within the solar module formation process sequence 100 to reduce or eliminate the occurrence of “dead” cells in the solar module formation process.

### General Solar Module Formation

To avoid confusion relating to the actions specifically performed on the substrates 302 in the following description, a substrate 302 having one or more of the deposited layers (e.g., the front contact layer 310, the PV layer 320, or the back contact layer 350) and/or one or more internal electrical connections (e.g., side buss 314, cross-buss 316) disposed thereon is referred to as a device substrate 303. Similarly, a device substrate 303 that has been bonded to a back glass substrate using a bonding material is referred to as a composite solar cell structure 304.

Referring to FIGS. 1 and 2, the process sequence 100 generally starts at step 102 in which a substrate 302 is loaded into a loading module 202 found in the solar module production line 200. In one embodiment, the substrates 302 are received in a “raw” state where the edges, overall size, and/or cleanliness of the substrates 302 are not well controlled. Receiving “raw” substrates 302 reduces the cost to prepare and store substrates 302 prior to forming a solar device and thus reduces the solar cell device cost, facilities costs, and production costs of the finally formed solar cell device. However, typically, it is advantageous to receive “raw” substrates 302 that have a transparent conducting oxide (TCO) layer (e.g., front contact layer 310) already deposited on a surface of the substrate 302 before it is received into the system in step 102. If a conductive layer is not deposited on the surface of the “raw” substrates then a front contact deposition step (step 107), which is discussed below, needs to be performed on a surface of the substrate 302.

Referring to FIGS. 1 and 2, in one embodiment, prior to performing step 108 the substrate 302 is transported to a front end processing module (not illustrated in FIG. 2) in which a front contact formation step 107 is performed on the substrate 302. In one embodiment, the front end processing module is similar to the processing module 218 discussed below. In step 107, one or more substrate front contact formation steps may include one or more preparation, etching and/or material deposition steps that are used to form the front contact regions on a bare solar cell substrate 302. In one embodiment, step 107 generally comprises one or more physical vapor deposition (PVD) steps that are used to form the front contact region on a surface of the substrate 302. In one embodiment, the front contact region contains a transparent conducting oxide (TCO) layer that may contain metal element selected from a group consisting of zinc (Zn), aluminum (Al), indium (In), and tin (Sn). In one example, a zinc oxide (ZnO) is used to form at least a portion of the front contact layer. In one embodiment, the front end processing module is an ATON™ PVD 5.7 tool available from Applied Materials in Santa Clara, Calif. in which one or more processing steps are performed to deposit the front contact formation steps. In another embodiment, one or more CVD steps are used to form the front contact region on a surface of the substrate 302.

Next, the device substrate 303 is transported to a scribe module 208 in which a front contact isolation step 108 is performed on the device substrate 303 to electrically isolate different regions of the device substrate 303 surface from each other. In step 108, material is removed from the device substrate 303 surface by use of a material removal step, such as a laser ablation process. The success criteria for step 108 are to achieve good cell-to-cell and cell-to-edge isolation while minimizing the scribe area. In one embodiment, a Nd:vanadate (Nd:YVO₄) laser source is used ablate material from the device substrate 303 surface to form lines that electrically isolate one region of the device substrate 303 from the next. In one embodiment, the laser scribe process performed during step 108 uses a 1064 nm wavelength pulsed laser to pattern the material disposed on the substrate 302 to isolate each of the individual solar cells 312 that make up the solar module 300. In one embodiment, a 5.7 m² substrate laser scribe module available from Applied Materials, Inc. of Santa Clara, Calif. is used to provide simple reliable optics and substrate motion for accurate electrical isolation of regions of the device substrate 303 surface. As shown in FIG. 4, the trench P1 may be formed in the front contact layer 310 via the front contact isolation step 108. One embodiment of a scribe module, such as the scribe module 208, is subsequently described in the “Scribe Module” section below. In another embodiment, a water jet cutting tool or diamond scribe is used to isolate the various regions on the surface of the device substrate 303.

Next, the device substrate 303 is transported to a processing module 212 in which step 112, which comprises one or more photoabsorber deposition steps, is performed on the device substrate 303. In step 112, the one or more photoabsorber deposition steps may include one or more preparation, etching, and/or material deposition steps that are used to form the various regions of the solar cell device. Step 112 generally comprises a series of sub-processing steps that are used to form the PV layer 320 of the solar module 300. In one embodiment, the PV layer 320 comprises one or more p-i-n junctions including amorphous silicon and/or microcrystalline silicon materials. In general, the one or more processing steps are performed in one or more cluster tools (e.g., cluster tools 212A-212D) found in the processing module 212 to form one or more layers in the solar cell device formed on the device substrate 303.

Next, the device substrate 303 is transported to a scribe module 216 in which an interconnect formation step 116 is performed on the device substrate 303 to electrically isolate various regions of the device substrate 303 surface from each other. In step 116, material is removed from the device substrate 303 surface by use of a material removal step, such as a laser ablation process. In one embodiment, an Nd:vanadate (Nd:YVO₄) laser source is used ablate material from the substrate surface to form lines that electrically isolate one solar cell from the next. In one embodiment, a 5.7 m² substrate laser scribe module available from Applied Materials, Inc. is used to perform the accurate scribing process. In one embodiment, the laser scribe process performed during step 108 uses a 532 nm wavelength pulsed laser to pattern the material disposed on the device substrate 303 to isolate the individual cells that make up the solar module 300. As shown in FIG. 4, in one embodiment, the trench P2 is formed in the PV layer 320 in the interconnect formation step 116. One embodiment of a scribe module, such as the scribe module 216, is subsequently described in the “Scribe Module” section below. In another embodiment, a water jet cutting tool or diamond scribe is used to isolate the various regions on the surface of the device substrate 303.

Next, the device substrate 303 may be transported to an inspection module 217 in which an inspection step 117 may be performed and metrology data may be collected and sent to the system controller 290. In one embodiment of the inspection step 117, as the device substrate 303 passes through the inspection module 217, the devise substrate 303 is optically inspected, and images of the device substrate 303 are captured and sent to the system controller 290, where the images are analyzed and metrology data is collected and stored in memory. In one embodiment, the metrology data is used to modify one or more upstream processes, such as the front contact isolation step 108 and/or the interconnect formation step 116. One embodiment of an inspection module 217 and processes performed during the inspection step 117 is subsequently described in the “Inspection Module and Processes” section.

Next, the device substrate 303 is transported to the processing module 218 in which a back contact formation step 118 is performed on the device substrate 303. In step 118, one or more substrate back contact formation steps are performed, which may include one or more preparation, etching, and/or material deposition steps that are used to form the back contact regions of the solar cell device. In one embodiment, step 118 generally comprises one or more PVD steps that are used to form the back contact layer 350 on the surface of the device substrate 303. In one embodiment, the one or more PVD steps are used to form a back contact region that contains a metal layer selected from a group consisting of zinc (Zn), tin (Sn), aluminum (Al), copper (Cu), silver (Ag), nickel (Ni), and vanadium (V). In one example, a zinc oxide (ZnO) or nickel vanadium alloy (NiV) is used to form at least a portion of the back contact layer 350. In one embodiment, the one or more processing steps are performed using an ATON™ PVD 5.7 tool available from Applied Materials in Santa Clara, Calif. In another embodiment, one or more CVD steps are used to form the back contact layer 350 on the surface of the device substrate 303.

Next, the device substrate 303 is transported to a scribe module 220 in which a back contact isolation step 120, is performed on the device substrate 303 to electrically isolate the plurality of solar cells 312 contained on the device substrate 303 surface from each other. In step 120, material is removed from the substrate surface by use of a material removal step, such as a laser ablation process. In one embodiment, a Nd:vanadate (Nd:YVO₄) laser source is used ablate material from the device substrate 303 surface to form lines that electrically isolate one solar cell from the next. In one embodiment, a 5.7 m² substrate laser scribe module, available from Applied Materials, Inc., is used to accurately scribe the desired regions of the device substrate 303. In one embodiment, the laser scribe process performed during step 120 uses a 532 nm wavelength pulsed laser to pattern the material disposed on the device substrate 303 to isolate the individual solar cells 312 that make up the solar module 300. As shown in FIG. 4, in one embodiment, the trench P3 is formed in the back contact layer 350 and the PV layer 320 by use of a laser scribing process. One embodiment of a scribe module, such as the scribe module 220, is subsequently described in the “Scribe Module” section below. In another embodiment, a water jet cutting tool or diamond scribe is used to isolate the various regions on the surface of the device substrate 303.

Next, the device substrate 303 may be transported to an inspection module 221 in which an inspection step 121 may be performed and metrology data may be collected and sent to the system controller 290. In one embodiment of the inspection step 121, as the device substrate 303 passes through the inspection module 221, the substrate is optically inspected, and images of the device substrate 303 are captured and sent to the system controller 290, where the images are analyzed and metrology data is collected and stored in memory. In one embodiment, the metrology data is used to modify one or more upstream processes, such as the front contact isolation step 108, the interconnect formation step 116, and/or the back contact isolation step 120. One embodiment of an inspection module 221 and processes performed during the inspection step 121 is subsequently described in the “Inspection Module and Processes” section.

Referring back to FIGS. 1 and 2, the device substrate 303 is next transported to the seamer/edge deletion module 226 in which a substrate surface and edge preparation step 126 is used to prepare various surfaces of the device substrate 303 to prevent yield issues later on in the process. In one embodiment of step 126, the device substrate 303 is inserted into seamer/edge deletion module 226 to prepare the edges of the device substrate 303 to shape and prepare the edges of the device substrate 303. Damage to the device substrate 303 edge can affect the device yield and the cost to produce a usable solar cell device. In another embodiment, the seamer/edge deletion module 226 is used to remove deposited material from the edge of the device substrate 303 (e.g., 10 mm) to provide a region that can be used to form a reliable seal between the device substrate 303 and the backside glass (i.e., steps 134-136 discussed below). Material removal from the edge of the device substrate 303 may also be useful to prevent electrical shorts in the final formed solar cell.

In one embodiment, a diamond impregnated belt is used to grind the deposited material from the edge regions of the device substrate 303. In another embodiment, a grinding wheel is used to grind the deposited material from the edge regions of the device substrate 303. In another embodiment, dual grinding wheels are used to remove the deposited material from the edge of the device substrate 303. In yet another embodiment, grit blasting or laser ablation techniques are used to remove the deposited material from the edge of the device substrate 303. In one aspect, the seamer/edge deletion module 226 is used to round or bevel the edges of the device substrate 303 by use of shaped grinding wheels, angled and aligned belt sanders, and/or abrasive wheels.

Next the device substrate 303 is transported to the pre-screen module 227 in which optional pre-screen steps 127 are performed on the device substrate 303 to assure that the devices formed on the substrate surface meet a desired quality standard. In step 127, a light emitting source and probing device are used to measure the output of the formed solar cell device by use of one or more substrate contacting probes. If the module 227 detects a defect in the formed device it can take corrective actions or the solar cell can be scrapped.

Next the substrate 303 is transported to a bonding wire attach module 231 in which step 131, or a bonding wire attach step, is performed on the substrate 303. Step 131 is used to attach the various wires/leads required to connect the various external electrical components to the formed solar cell device. Typically, the bonding wire attach module 231 is an automated wire bonding tool that is advantageously used to reliably and quickly form the numerous interconnects that are often required to form the large solar cells formed in the production line 200. In one embodiment, the bonding wire attach module 231 is used to form the side-buss 314 (FIG. 3) and cross-buss 316 on the formed back contact layer 350 (step 118). In this configuration the side-buss 314 may be a conductive material that can be affixed, bonded, and/or fused to the back contact layer 350 found in the back contact region to form a good electrical contact. In one embodiment, the side-buss 314 and cross-buss 316 each comprise a metal strip, such as copper tape, a nickel coated silver ribbon, a silver coated nickel ribbon, a tin coated copper ribbon, a nickel coated copper ribbon, or other conductive material that can carry the current delivered by the solar cell and be reliably bonded to the metal layer in the back contact region. In one embodiment, the metal strip is between about 2 mm and about 10 mm wide and between about 1 mm and about 3 mm thick. The cross-buss 316, which is electrically connected to the side-buss 314 at the junctions, can be electrically isolated from the back contact layer(s) of the solar cell by use of an insulating material, such as an insulating tape. The ends of each of the cross-busses 316 generally have one or more leads that are used to connect the side-buss 314 and the cross-buss 316 to the electrical connections found in a junction box 308, which is used to connect the formed solar cell to the other external electrical components.

In the next step, step 132, a bonding material and “back glass” substrate are prepared for delivery into the solar cell formation process (L e., process sequence 100). The preparation process is generally performed in the glass lay-up module 232, which generally comprises a material preparation module 232A, a glass loading module 232B, a glass cleaning module 232C, and a glass inspection module 232D. The back glass substrate is bonded onto the device substrate 303 formed in steps 102-131 above by use of a laminating process (step 134 discussed below). In general, step 132 requires the preparation of a polymeric material that is to be placed between the back glass substrate and the deposited layers on the device substrate 303 to form a hermetic seal to prevent the environment from attacking the solar cell during its life. Referring to FIG. 2, step 132 generally comprises a series of sub-steps in which a bonding material is prepared in the material preparation module 232A, the bonding material is then placed over the device substrate 303, and the back glass substrate is loaded into the loading module 232B. The back glass substrate is washed by the cleaning module 232C. The back glass substrate is then inspected by the inspection module 232D, and the back glass substrate is placed over the bonding material and the device substrate 303.

In the next sub-step of step 132, the back glass substrate is transported to the cleaning module 232C in which a substrate cleaning step, is performed on the substrate to remove any contaminants found on the surface of the substrate. Common contaminants may include materials deposited on the substrate during the substrate forming process (e.g., glass manufacturing process) and/or during shipping of the substrates. Typically, the cleaning module 232C uses wet chemical scrubbing and rinsing steps to remove any undesirable contaminants as discussed above.

The prepared back glass substrate is then positioned over the bonding material and partially device substrate 303 by use of an automated robotic device.

Next the device substrate 303, the back glass substrate, and the bonding material are transported to the bonding module 234 in which step 134, or lamination steps are performed to bond the backside glass substrate to the device substrate formed in steps 102-132 discussed above. In step 134, a bonding material, such as Polyvinyl Butyral (PVB) or Ethylene Vinyl Acetate (EVA), is sandwiched between the backside glass substrate and the device substrate 303. Heat and pressure are applied to the structure to form a bonded and sealed device using various heating elements and other devices found in the bonding module 234. The device substrate 303, the back glass substrate and bonding material thus form a composite solar cell structure 304 that at least partially encapsulates the active regions of the solar cell device. In one embodiment, at least one hole formed in the back glass substrate remains at least partially uncovered by the bonding material to allow portions of the cross-buss 316 or the side buss 314 to remain exposed so that electrical connections can be made to these regions of the solar cell structure 304 in future steps (i.e., step 138).

Next the composite solar cell structure 304 is transported to the autoclave module 236 in which step 136, or autoclave steps are performed on the composite solar cell structure 304 to remove trapped gasses in the bonded structure and assure that a good bond is formed during step 136. In step 136, a bonded solar cell structure 304 is inserted in the processing region of the autoclave module where heat and high pressure gases are delivered to reduce the amount of trapped gas and improve the properties of the bond between the device substrate 303, back glass substrate, and bonding material. The processes performed in the autoclave are also useful to assure that the stress in the glass and bonding layer (e.g., PVB layer) are more controlled to prevent future failures of the hermetic seal or failure of the glass due to the stress induced during the bonding/lamination process. In one embodiment, it may be desirable to heat the device substrate 303, back glass substrate, and bonding material to a temperature that causes stress relaxation in one or more of the components in the formed solar cell structure 304.

Next the solar cell structure 304 is transported to the junction box attachment module 238 in which junction box attachment steps 138 are performed on the formed solar cell structure 304. The junction box attachment module 238, used during step 138, is used to install a junction box 308 (FIG. 3) on a partially formed solar module. The installed junction box 308 acts as an interface between the external electrical components that will connect to the formed solar module, such as other solar modules or a power grid, and the internal electrical connections points, such as the leads, formed during step 131. In one embodiment, the junction box 308 contains one or more connection points so that the formed solar module can be easily and systematically connected to other external devices to deliver the generated electrical power.

Next, the solar cell structure 304 is transported to the device testing module 240 in which device screening and analysis steps 140 are performed on the solar cell structure 304 to assure that the devices formed on the solar cell structure 304 surface meet desired quality standards. In one embodiment, the device testing module 240 is a solar simulator module that is used to qualify and test the output of the one or more formed solar cells. In step 140, a light emitting source and probing device are used to measure the output of the formed solar cell device by use of one or more automated components that are adapted to make electrical contact with terminals in the junction box 308. If the module detects a defect in the formed device it can take corrective actions or the solar cell can be scrapped.

Next the solar cell structure 304 is transported to the support structure module 241 in which support structure mounting steps 141 are performed on the solar cell structure 304 to provide a complete solar cell device that has one or more mounting elements attached to the solar cell structure 304 formed using steps 102-140 to a complete solar cell device that can easily be mounted and rapidly installed at a customer's site.

Next the solar cell structure 304 is transported to the unload module 242 in which step 142, or device unload steps are performed on the substrate to remove the formed solar cells from the solar module production line 200.

### Scribe Module

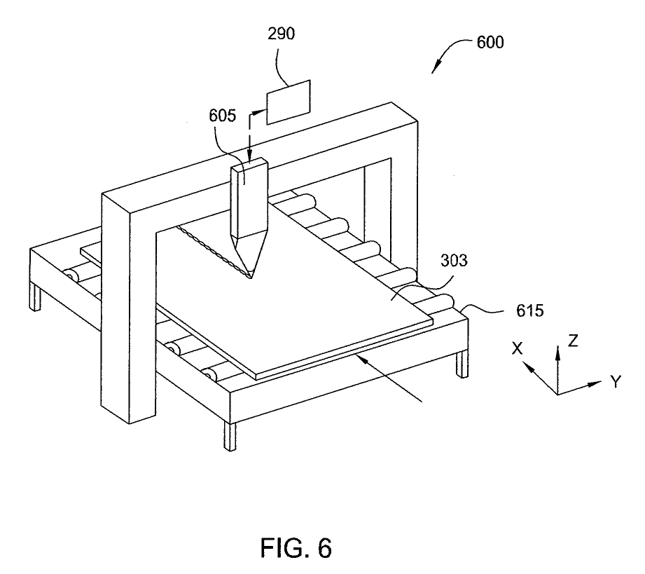

FIG. 6 is a schematic isometric view of a laser scribe module 600 that may be used for laser scribing a series of trenches (i.e., P1, P2, or P3) in one or more material layers (i.e., front contact layer 310, PV layer 320, or back contact layer 350) deposited on the solar cell substrate 302. In one embodiment, the laser scribe module 600 includes one or more laser scribing devices 605 and a substrate positioning table 615 in communication with a system controller 290. In one embodiment, the laser scribing device 605 generally includes a laser source (e.g., Nd:YVO₄ laser), various optics, and other support components that are used to control the power, energy, and timing of the delivery of energy used to scribe the desired trenches (e.g., P1, P2, or P3) into the respective layer (e.g., front contact layer 310, PV layer 320, or back contact layer 350) on the surface of the device substrate 303.

In one embodiment, the substrate positioning table 615 includes one or more components configured to position the device substrate 303 in the X direction, and one or more components for moving the device substrate 303 through the scribe module 600 in the Y direction. In one embodiment, based on desired programming, the system controller 290 instructs the substrate positioning table 615 to position the device substrate 303 in the desired location and to advance the device substrate 303 through the laser scribe module 600. The system controller 290 may further instruct the laser scribing device 605 to perform a laser scribe on the device substrate 303 to produce the desired trench (P1, P2, or P3).

In another embodiment, the laser scribing device 605 further comprises one or more components for moving the laser in the X direction, and one or more components for moving the laser scribing device in the Y direction. In this embodiment, based on desired programming, the system controller 290 instructs the laser scribing device 605 to position itself in the desired X location and then advance in the Y direction as it is performing a laser scribe on the device substrate 303 to produce the desired trench (P1, P2, or P3).

### Inspection Module and Processes

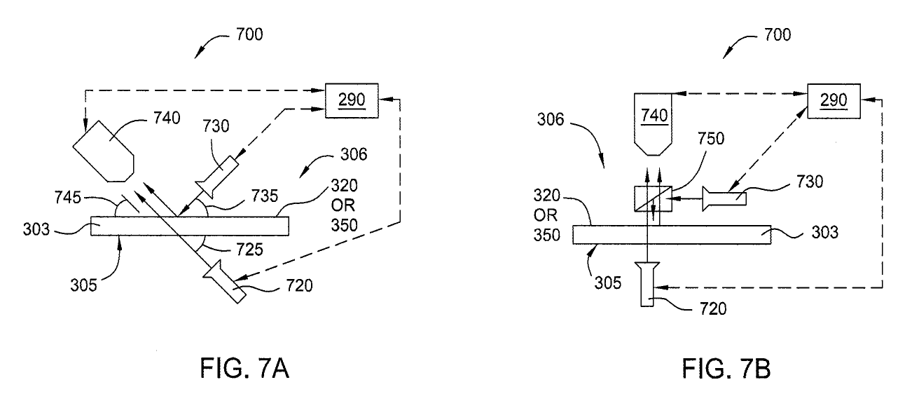

FIG. 7A is a schematic, cross-sectional view of an inspection module 700, such as the inspection module 217 (FIG. 2) or the inspection module 221 (FIG. 2), according to one embodiment of the present invention. In one embodiment, the inspection module 700 is directly incorporated into the scribe modules 216 and/or 220 (FIG. 2). In one embodiment, the inspection module 700 comprises a back side illumination source 730, an inspection device 740, and optionally, a front side illumination source 720. In an embodiment that includes the optional front side illumination source 720, the front side illumination source 720 is positioned below the device substrate 303 and is configured to emit light toward the front surface 305 of the device substrate 303 at an angle 725 with respect to the surface of the device substrate 303. In one embodiment, the angle 725 is between about 15° and about 90°. In one embodiment, the angle 725 is between about 60° and about 90°. In one embodiment, the angle 725 is between about 75° and about 90°. In one embodiment, the optional front side illumination source 720 is positioned to emit light normal to the surface of the device substrate 303. In one embodiment, the front side illumination source 720 is a broad band light source. In one embodiment, the broad band type front side illumination source 720 includes one or more filters to control the wavelength of light emitted therefrom. In one embodiment, the front side illumination source 720 is configured to emit wavelengths of light only in a particular spectrum, such as the blue spectrum. In one example, the front side illumination source 720 is adapted to emit electromagnetic radiation in wavelengths between about 400 nm and about 900 nm. In one embodiment, the front side illumination source 720 is adapted to emit electromagnetic radiation in wavelengths between about 450 nm and about 500 nm. In one embodiment, the front side illumination source 720 is in communication with the system controller 290.

In one embodiment, the back side illumination source 730 is positioned above the device substrate 303 and is configured to emit light toward the back surface 306 of the device substrate 303 having the PV layer 320 (in the case of the inspection module 217) or the back contact layer 350 (in the case of the inspection module 221) deposited thereon. In one embodiment, the back side illumination source 730 is configured to emit light toward the device substrate 303 at an angle 735 with respect to the surface thereof. In one embodiment, the angle 735 is between about 10° and about 90°. In one embodiment, the angle 735 is between about 60° and about 90°. In one embodiment, the angle 735 is between about 75° and about 89°. In one embodiment, the angle 735 is substantially complementary to the angle 725. In one embodiment, the back side illumination source 730 is a broad band light source. In one embodiment, the broad band type back side illumination source 730 includes one or more filters to control the wavelength of light emitted therefrom. In one embodiment, the back side illumination source 730 is configured to emit wavelengths of light only in a particular spectrum, such as the red spectrum. In one example, the back side illumination source 730 is adapted to emit electromagnetic radiation in wavelengths between about 400 nm and about 900 nm. In one embodiment, the back side illumination source 730 is adapted to emit electromagnetic radiation in wavelengths between about 600 nm and about 750 nm. In one embodiment, the back side illumination source 730 is in communication with the system controller 290.

In one embodiment, the inspection device 740 comprises one or more cameras, such as CCD cameras, and other supporting components that are used to conduct optical inspection of the scribed trenches P1, P2, and/or P3. In one embodiment, the inspection device 740 comprises one or more CCD cameras positioned above the device substrate 303 and configured to capture images at an angle 745 with respect to the surface of the device substrate 303. The resolution of the inspection device 740 should be selected such that each of the scribed trenches P2, P2, and/or P3 is visible for analysis of the position, shape, and orientation of each. In one embodiment, the angle 745 is between about 10° and about 90°. In one embodiment, the angle 745 is between about 60° and about 90°. In one embodiment, the angle 745 is between about 75° and about 89°. In one embodiment, the angle 745 is substantially equal to the angle 735. In one embodiment, the angle 745 is substantially complementary to the angle 735. In one embodiment, the inspection device 740 is in communication with the system controller 290.

FIG. 7B is a schematic, cross-sectional view of an alternate embodiment of the inspection module 700. In the embodiment shown in FIG. 7B, the inspection module 700 further comprises a beam splitter 750. In an embodiment that includes the optional front side illumination source 720, the front side illumination source 720 is positioned below the device substrate 303 and is configured to emit light in a direction substantially perpendicular to the front surface 305 of the device substrate 303. In one embodiment, the back side illumination source 730 is positioned above the device substrate 303 and is configured to emit light toward the beam splitter 750 in a direction substantially parallel to the surface of the device substrate 303. In one embodiment, the inspection device 740 is positioned above the device substrate 303 and is configured to capture images substantially perpendicular to the surface of the device substrate 303.

Referring to FIGS. 2, 7A, and 7B, in one embodiment, the inspection module 700 is positioned within the production line 200 (e.g., inspection modules 217 and 221) to receive a device substrate 303 from the automation device 281. The automation device 281 may feed the device substrate 303 below the inspection device 740 and back side illumination source 730. In one embodiment as the device substrate 303 is fed through the inspection module 700, the device substrate 303 is illuminated by the back side illumination source 730 as the inspection device 740 captures images of one or more regions of the substrate surface. In an embodiment that includes the optional front side illumination source 720, the front side illumination source 720 and the back side illumination source 730 illuminate the device substrate 303 as it is fed through the inspection module 700. In the embodiment depicted in FIG. 7A, light is emitted by the back side illumination source 730 at the angle 735 with respect to the surface of the device substrate 303 so that an image of one or more regions of the substrate surface can be captured by the inspection device 740 (i.e., reflection channel). In an embodiment that includes the front side illumination source 720, light is simultaneously emitted from the front side illumination source 720 at the angle 725 with respect to the device substrate 303 so that an image of one or more regions of the substrate surface can be captured by the inspection device 740 (i.e., transmission channel). Correspondingly, in the embodiment depicted in FIG. 7B, light is emitted by the back side illumination source 730 toward the beam splitter 750, substantially parallel to the device substrate 303, so that an image of one or more regions of the substrate surface can be captured by the inspection device 740 (i.e., reflection channel). In an embodiment that includes the optional front side illumination source 720, light is simultaneously emitted from the front side illumination source 720 substantially perpendicular to the device substrate 303 so that an image of one or more regions of the substrate surface can be captured by the inspection device 740 (i.e., transmission channel). The resulting images captured through the reflection channel, in one embodiment, or the combination of transmission and reflection channels, in another embodiment, provide a clear representation of all of the scribed trenches P1, P2, and/or P3 for analysis and storage by the system controller 290 and/or additional manual analysis.

The inspection device 740 sends the captured images of the device substrate 303 to the system controller 290, where the images are analyzed and metrology data is collected and stored. In one embodiment, the images are retained by portions of the system controller 290 disposed locally within the inspection module 700 for analysis. In one embodiment, the system controller 290 uses the information supplied by the inspection device 740 to determine whether the device substrate 303 meets specified criteria. For instance, the images may be used to identify any overlap that may exist between the scribed trenches P1, P2, and/or P3 or any missing scribed trenches P1, P2, and P3 that result in a shorted or “dead” solar cell 312 in the fully formed solar module 300. Additionally, the general waviness, parallelism, and spacing of the scribed trenches P1, P2, and P3 may be analyzed. In one embodiment, the information provided by the inspection module 700 is used by the system controller 290 to reject a particular device substrate 303, which has one or more overlapping scribed trenches P1, P2, and/or P3, which may be scrapped. In one embodiment, based on the information received from the inspection module 700 (L e., inspection module 217, 221), the system controller 290 may instruct that a device substrate 303 be sent back through the appropriate scribe module 600 (i.e., 216 or 220) for corrective action.

In one embodiment, information gathered in the inspection module 700 (i.e., inspection module 217, 221) is used by the system controller 290 (either manually or in an automated fashion) to alter and tune processing parameters in the corresponding scribe module 600 (i.e., scribe module 208, 216, 220) for device substrates 303 subsequently processed in the production line 200. For example, the system controller 290 may identify a consistent problem with one or more of the scribe trenches P1 and P2 (e.g., waviness, parallelism, spacing, missing lines) from the information received from the inspection module 217. The system controller 290 may use this information to alter the processing parameters within the scribe module 208 and/or 216 to improve the quality of the scribed trenches P1 and/or P2 for subsequently processed device substrates 303. In another example, the system controller 290 may identify a consistent problem with one or more of the scribe lines P1, P2, and P3 (e.g., waviness, parallelism, spacing, missing lines) from the information received from the inspection module 221. The system controller 290 may use this information to alter the processing parameters within the scribe module 208, 216, and/or 220 to improve the quality of the scribed trenches P1, P2, and/or P3 for subsequently processed device substrates 303.

In one embodiment, adjustments to the scribe module 600 (i.e., 208, 216, 220) comprise adjusting the alignment and movement of the device substrate 303 with respect to the laser scribing device 605. In another embodiment, adjustments to the scribe module 600 (i.e., 208, 216, 220) comprise adjusting the alignment and movement of the laser scribing device 605 with respect to the device substrate 303. In one embodiment, adjustments to the scribe module 600 (i.e., 208, 216, 220) comprise adjustments to the laser scribing device 605, such as the frequency or output current of the laser scribing device 605, among other laser device parameters.

While the foregoing is directed to embodiments of the present invention, other and further embodiments of the invention may be devised without departing from the basic scope thereof, and the scope thereof is determined by the claims that follow.

1. An apparatus for inspecting scribed trenches in a partially formed solar module, comprising:
a first illumination source positioned to illuminate a back surface of the partially formed solar module;
an inspection device positioned to capture an image of a region of the back surface of the partially formed solar module; and
a system controller in communication with the first illumination source and the inspection device, wherein the system controller is configured to receive and analyze the image received from the inspection device.

2. The apparatus of claim 1, wherein the first illumination source is positioned to emit light at an angle between about 75° and about 89° with respect to the back surface, and wherein the inspection device is positioned at an angle between about 75° and about 89° with respect to the back surface.

3. The apparatus of claim 1, further comprising a beam splitter, wherein the first illumination source is positioned to emit light substantially parallel to the back surface, and wherein the inspection device is positioned substantially perpendicular to the back surface.

4. The apparatus of claim 1, further comprising a second illumination source positioned to illuminate a front surface of the partially formed solar module, wherein the system controller is further in communication with the second illumination source.

5. The apparatus of claim 4, wherein the second illumination source is configured to illuminate the front surface of the partially formed solar module with light having wavelengths only in the blue spectrum, and wherein the first illumination source is configured to illuminate the back surface of the partially formed solar module with light having wavelengths only in the red spectrum.

6. The apparatus of claim 4, wherein the second illumination source is positioned to emit light at an angle between about 75° and about 90° with respect to the front surface, wherein the first illumination source is positioned to emit light at an angle between about 75° and about 89° with respect to the back surface, and wherein the inspection device is positioned at an angle between about 75° and about 89° with respect to the back surface.

7. The apparatus of claim 4, further comprising a beam splitter, wherein the second illumination source is positioned to emit light substantially perpendicular to the front surface, wherein the first illumination source is positioned to emit light substantially parallel to the back surface, and wherein the inspection device is positioned substantially perpendicular to the back surface.

8. A method of inspecting scribed trenches in a partially formed solar module, comprising:
receiving the partially formed solar module having at least a front contact layer disposed thereon with one or more first trenches scribed in the front contact layer and a photovoltaic layer disposed over the front contact layer having one or more second trenches scribed in the photovoltaic layer;
illuminating a back surface of the partially formed solar module; and
optically inspecting a region of the partially formed solar module having at least a portion of the one or more first trenches and at least a portion of the one or more second trenches disposed therein while illuminating the back surface of the partially formed solar module, wherein optically inspecting comprises capturing an image of the region and analyzing a position or orientation of the portion of the one or more first trenches relative to the portion of the one or more second trenches.

9. The method of claim 8, wherein illuminating the back surface comprises emitting light at an angle from between about 75° and about 89° with respect to the back surface, and wherein optically inspecting comprises capturing an image of the region with an inspection device positioned at an angle from between about 75° and about 89° with respect to the back surface.

10. The method of claim 9, further comprising illuminating a front surface of the partially formed solar module, wherein illuminating the front surface comprises emitting light at an angle from between about 75° and about 90° with respect to the front surface, and wherein the optically inspecting is performed while illuminating the front and back surfaces.

11. The method of claim 8, wherein illuminating the back surface comprises emitting light substantially parallel to the back surface, and wherein optically inspecting comprises capturing an image of the region with an inspection device positioned substantially perpendicular to the back surface.

12. The method of claim 11, further comprising illuminating a front surface of the partially formed solar module, wherein illuminating the front surface comprises emitting light substantially perpendicular to the front surface, and wherein the optically inspecting is performed while illuminating the front and back surfaces.

13. A system for fabricating solar modules, comprising:
a first scribing module configured to scribe one or more first trenches in a front contact layer of a solar cell substrate;
one or more cluster tools having at least one chamber configured to deposit at least one photovoltaic layer over the front contact layer;
a second scribing module configured to scribe one or more second trenches in the at least one photovoltaic layer;
a first optical inspection module having a first illumination source and an inspection device configured to capture an image of at least a portion of the first and second trenches; and
a system controller in communication with at least the first scribing module, the second scribing module and the optical inspection module, wherein the system controller is configured to receive and analyze the image of the portion of the first and second trenches, and wherein the system controller is configured to alter parameters of at least one of the first and second scribing modules in response to the analyzed image.

14. The system of claim 13, wherein the first illumination source of the first optical inspection module is positioned to illuminate a back surface of the solar cell substrate, and wherein the inspection device is positioned to capture an image from the back surface of the solar cell substrate.

15. The system of claim 14, wherein the first illumination source is positioned to emit light at an angle between about 75° and about 89° with respect to the back surface, and wherein the inspection device is positioned at an angle between about 75° and about 89° with respect to the back surface.

16. The system of claim 14, wherein the first inspection module further comprises a beam splitter, wherein the first illumination source is positioned to emit light substantially parallel to the back surface, and wherein the inspection device is positioned substantially perpendicular to the back surface.

17. The system of claim 14, further comprising:
a deposition module configured to deposit a back contact layer over the at least one photovoltaic layer;
a third scribing module configured to scribe one or more third trenches in the back contact layer; and
a second optical inspection module having a first illumination source and an inspection device configured to capture an image of a portion of the first, second, and third trenches, wherein the system controller is further in communication with the deposition module, the third scribing module, and the second optical inspection module, and wherein the system controller is further configured to receive and analyze the image of the portion of the first, second, and third trenches, and wherein the system controller is further configured to alter parameters of at least one of the first, second, and third scribing modules in response to the analyzed images.

18. The system of claim 17, wherein the first optical inspection module further comprises a second illumination source positioned to illuminate a front surface of the substrate, and wherein the second optical inspection module further comprises a second illumination source positioned to illuminate the front surface of the substrate.

19. The system of claim 18, wherein each of the first illumination sources is positioned to emit light at an angle between about 75° and about 90° with respect to the front surface, wherein each of the second illumination sources is positioned to emit light at an angle between about 75° and about 89° with respect to the back surface, and wherein each of the inspection device is positioned at an angle between about 75° and about 89° with respect to the back surface.

20. The system of claim 16, wherein each of the first and second inspection modules further comprises a beam splitter, wherein each of the first illumination sources is positioned to emit light substantially perpendicular to the front surface, wherein each of the second illumination sources is positioned to emit light substantially parallel to the back surface, and wherein each of the inspection devices is positioned substantially perpendicular to the back surface.

21. A process for fabricating solar modules, comprising:
receiving a solar cell substrate having at least a front contact layer disposed thereon;
scribing one or more first trenches in the front contact layer via a first scribing module;
depositing a photovoltaic layer over the front contact layer;
scribing one or more second trenches in the photovoltaic layer via a second scribing module;
capturing an image of at least a portion of the first and second trenches while illuminating a back surface of the solar cell substrate;
analyzing the captured image of the at least a portion of the first and second trenches by analyzing a position or orientation of at least a portion of the one or more first trenches with respect to at least a portion of the one or more second trenches; and
altering one or more process parameters of at least one of the first and second scribing modules based on the analyzed image of the at least a portion of the first and second trenches.

22. The process of claim 21, further comprising:
depositing a back contact layer over the photovoltaic layer;
scribing one or more third trenches in the back contact layer via a third scribing module;
capturing an image of at least a portion of the first, second, and third trenches while illuminating the back surface of the solar cell substrate;
analyzing the captured image of the at least a portion of the first, second, and third trenches by analyzing a position or orientation of at least a portion of the one or more second trenches with respect to at least a portion of the one or more third trenches; and
altering one or more process parameters of at least one of the first, second, and third scribing modules based on the analyzed image of the at least a portion of the first, second, and third trenches.

23. The process of claim 22, wherein the capturing an image of at least a portion of the first and second trenches is performed while further illuminating a front surface of the solar cell substrate, and wherein the capturing an image of at least a portion of the first, second, and third trenches is performed while further illuminating a front surface of the solar cell substrate.

24. The process of claim 23, wherein illuminating the front surface comprises emitting light at an angle from between about 75° and about 90° with respect to the front surface, wherein illuminating the back surface comprises emitting light at a angle from between about 75° and about 89° with respect to the back surface, and wherein the capturing the image comprises capturing an image with an inspection device positioned at an angle from between about 75° and about 89° with respect to the back surface.

25. The process of claim 23, wherein illuminating the front surface comprises emitting light substantially perpendicular to the front surface, wherein illuminating the back surface comprises emitting light substantially parallel to the back surface, and wherein the capturing the image comprises capturing an image with an inspection device positioned substantially perpendicular to the back surface.
